(19) United States
(12) Patent Application Publication
(10) Pub. No.: US 2015/0073737 A1
(43) Pub. Date: Mar. 12, 2015

(54) POWER MONITORING APPARATUS AND POWER MONITORING METHOD

(71) Applicant: Tatsuki Inuzuka, Tokyo (JP)

(72) Inventor: Tatsuki Inuzuka, Tokyo (JP)

(21) Appl. No.: 14/394,840

(22) PCT Filed: Apr. 20, 2012
(86) PCT No.: PCT/JP2012/060714

§ 371 Date: Oct. 16, 2014

(51) Int. Cl. G01R 21/00; G01R 21/133

(52) U.S. Cl. CPC G01R 21/006; G01R 21/133
USPC 702/61

(57) ABSTRACT

A characteristic of a solar power generation device in a customer facility is calculated. A power monitoring apparatus includes an acquisition unit and a calculation unit. The acquisition unit acquires, for a first electrical facility including a first solar power generation device and a first load device, a first insolation signal indicating change of insolation to the first solar power generation device over time and a first load signal indicating change of a load, as a combination of the first solar power generation device and the first load device, over time, from a storage device. The calculation unit calculates a first power generation characteristic indicating a characteristic of a power generation amount of the first solar power generation device with respect to the first insolation signal, based on the first insolation signal and the first load signal.

### TECHNICAL FIELD

This invention relates to a technique of monitoring power of a solar power generation device and a load device connected to an electrical grid.

### BACKGROUND ART

An operation state of an electrical grid changes when devices that generate and consume power, devices that change the characteristics of the devices, and the like are coupled to the electrical grid. For example, when a solar power generation device and a load device are connected to a distribution grid in the electrical grid, a PV power generation amount and a load amount of the devices are combined. The solar power generation device will be hereinafter referred to as PV (Photovoltaic) device. The adoption rate of the PV device is expected to rise, and to evaluate how the electrical grid is affected, the power generation amount of the PV device is preferably identifiable. When a grid is separated, due to any reason, to evaluate the power supply and demand of the separated grid, preferably, the PV power generation amount in the separated grid is able to be estimated. When a full amount purchase system of the PV power generation is implemented, it is a matter of course that the power generation amount of the PV device in each customer facility is preferably identifiable.

A meter known as AMI (Automatic Metering Infrastructure) has recently been introduced in each customer facility. The AMI measures a physical amount related to power at a connection point between the customer facility and the distribution grid. The meter is referred to as a smart meter in some cases. In the description below, the terms such as meter, AMI, smart meter, and power meter are treated as the same element. An amount of power generated by the PV device is referred to as a PV power generation amount. An amount of power consumed by the load device is referred to as an actual load. In a case where the measurement target of the meter is an apparent load obtained by combining the PV power generation amount and the actual load, it is impossible to individually identify the PV power generation amount and the actual load. Specifically, when the customer facility does not include a sensor that individually measure the PV power generation amount and the actual load, to individually identify the PV power generation amount and the actual load, the values need to be estimated.

For example, a separation method for separating the PV power generation amount and the load amount from each other in the distribution grid, by using ICA (Independent component analysis) has been known. In the method, the target is a single feeder section of the distribution grid. Here, relatively short term fluctuations of the load amount and the PV power generation amount flowing through the section are regarded as having no correlation. The separation method separates the PV power generation amount and the load amount from each other through the following procedures ST1 to ST5.

(ST1) short term signal extraction

(ST2) ICA application

(ST3) separated signal sorting

(ST4) scaling

(ST5) estimation value calculation

Furthermore, a method for estimating the load amount in the distribution grid by also using the ICA has been known. In this method, the model of the distribution grid and the use of the ICA are the same as those in the separation method described above, and extraterrestrial insolation is also used as insolation.

Furthermore, a theoretical (empirical) formula for calculating insolation related to the PV power generation amount has been known.

Furthermore, a technique of predicting the solar power generation amount has been known that is based on a fluctuation of an unbalance factor of three-phase alternate current caused by the power generation by a solar power generation device connected to the distribution grid (for example PTL 1).

### CITATION LIST

### Patent Literature

### [PTL 1]

Japanese Patent Application Publication No. 2011-41384

### SUMMARY OF INVENTION

### Technical Problem

The of the ICA as a method for separating the combined load amount and PV power generation amount in the distribution grid has the following problems PR1 to PR3.

(PR1) Due to the principle characteristic of the ICA, the accuracy of the calculation depends on whether a signal of a signal source is close to a Gaussian distribution.

(PR2) The ICA has a problem that the order of the separated signals are not uniquely determined (also referred to as Permutation problem).

(PR3) When the ICA is applied, as a model of the distribution grid, active power P and reactive power Q are used. In many cases, a power factor on which Q is based is difficult to measure.

A method for analyzing the distribution grid cannot separate the PV power generation amount and the load amount in each customer facility from each other.

### Solution to Problem

To solve the problems described above, a power monitoring apparatus according to an aspect of this invention includes an acquisition unit and a calculation unit. The acquisition unit acquires, for a first electrical facility including a first solar power generation device and a first load device, a first insolation signal indicating change of insolation to the first solar power generation device over time and a first load signal indicating change of a load, as a combination of the first solar power generation device and the first load device, over time, from a storage device. The calculation unit calculates a first power generation characteristic indicating a characteristic of a power generation amount of the first solar power generation device with respect to the first insolation signal, based on the first insolation signal and the first load signal.

### Advantageous Effects of Invention

With this invention, a characteristic of a solar power generation device in a customer facility can be calculated.

### BRIEF DESCRIPTION OF DRAWINGS

FIG. 1 shows a configuration of a power monitoring system according to Example 1.

FIG. 2 shows a wiring method B.

FIG. 3 shows a wiring method C.

FIG. 4 shows inputs and outputs to and from a power monitoring apparatus according to Example 1.

FIG. 5 shows a configuration of the power monitoring apparatus.

FIG. 6 shows monitoring processing.

FIG. 7 shows selection processing.

FIG. 8 shows a signal used by the selection processing.

FIG. 9 shows update processing.

FIG. 10 shows estimation processing.

FIG. 11 shows insolation.

FIG. 12 shows a PV power generation amount.

FIG. 13 shows a configuration of a power monitoring system according to Example 2.

FIG. 14 shows inputs and outputs to and from a power monitoring unit according to Example 2.

FIG. 15 shows area estimation processing.

### DESCRIPTION OF EMBODIMENTS

Embodiments of this invention are described below by referring to the drawings and the like. The embodiments described below represent specific examples of the content of the invention of the present application. Thus, the invention of the present application is not limited to the embodiments, and can be modified and amended in various ways by a person skilled in the art within the scope of the technical idea disclosed in this specification.

### EXAMPLE 1

In this embodiment, a power monitoring system will be described that estimates a PV power generation amount and an actual load in a customer facility.

<<Configuration of Power Monitoring System>>

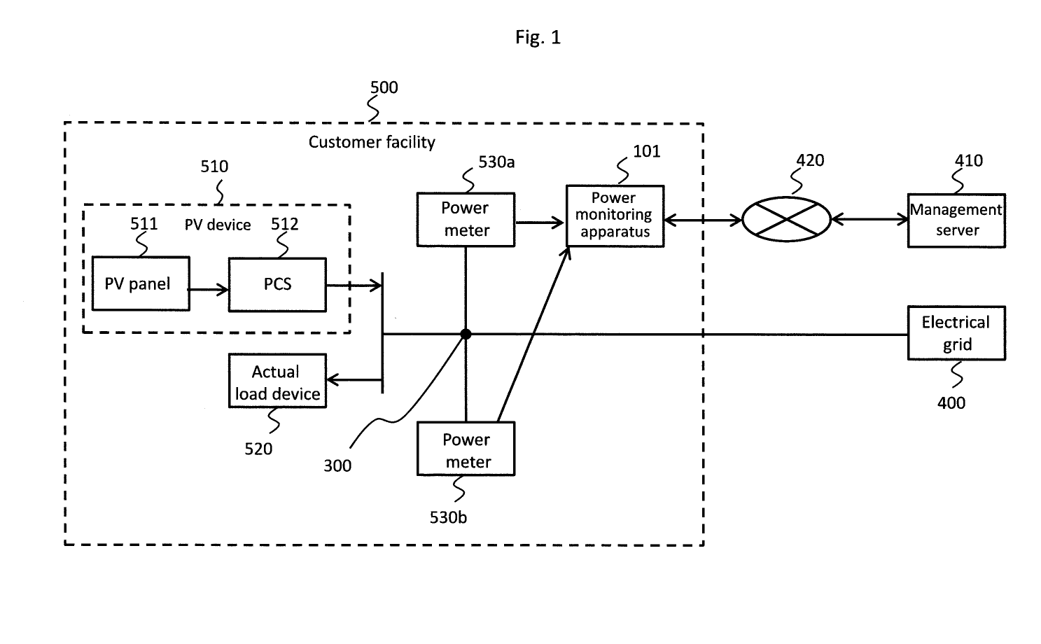

FIG. 1 shows a configuration of a power monitoring system according to Example 1. The power monitoring system includes an electrical grid 400, a customer facility 500, and a management server 410. The electrical grid 400 transmits power to the customer facility 500 or receives power generated by the customer facility 500. The management server 410 manages a power amount measured in the customer facility 500. The management server 410 is MDMS (Meter Data Management System) for example. The customer facility 500 includes a PV device 510, an actual load device 520, power meters 530a and 530b, a power monitoring apparatus 101, and a connection point 300.

The power monitoring apparatus 101 may be an energy management system such as HEMS (Home Energy Management System), or may be provided in the energy management system. The power monitoring apparatus 101 acquires a measurement Value of the power amount from the power meters 530a and 530b. The power monitoring apparatus 101 is coupled to, and thus communicates with the management server 410 through a communication network 420.

The power monitoring apparatus 101 and the power meters 530a and 530b may be included in an AMI. Voltage, current, active power, reactive power, phase, power factor, or the like is generally used as a physical quantity related to the power. In the measurement, what physical quantity is acquired at which measurement interval and with which signal resolution (the number of bits involved in A/D conversion) are determined under various conditions. Of the physical quantities, the description given below focuses on the effective power, but the content of the description can also be applied to the measurement of other physical quantities.

The PV device 510 generates power by receiving solar radiation. The PV device 510 includes a PV panel 511 and a PCS (Power Conditioning System) 512. The PCS 512 converts DC current from the PV panel 511 into AC current. The PV power generation amount, indicating the amount of power generated by the PV device 510, is approximately proportional to insolation input to the PV panel 511. Factors hindering the proportionality include temperature characteristics of the PV panel 511, and non-linear characteristics of the PCS 512. In the description below, the characteristics of the PV device 510 including these are referred to as a PV device characteristic, and the PV device characteristic is regarded as an output characteristic proportional to insolation.

The actual load device 520 is a group of various devices that consume power in the customer facility 500. The loads of the group of these devices are summed and referred to as an actual load.

The power meters 530a and 530b, which are connected to the connection point 300 between the customer facility 500 and the electrical grid 400, measure the power amount at the connection point 300 for billing. The power meters 530a and 530b respectively measure selling and purchasing power amounts, in accordance with a direction in which the power flows. In the description below, the power amount of the selling power in a direction toward the electrical grid 400 from the customer facility 500 is referred to as the selling power amount, and power amount of the purchasing power in a direction from the electrical grid 400 toward the customer facility 500 is referred to as the purchasing power amount. In this case, the purchasing power amount is measured as a result of subtracting the PV power generation amount from the actual load (apparent load), and thus the respective measurement values of the PV power generation amount and the actual load cannot be obtained. In the description below, a wiring method for measurement of power by the power meters 530a and 530b is referred to as a wiring method A.

Now, other wiring methods will be described.

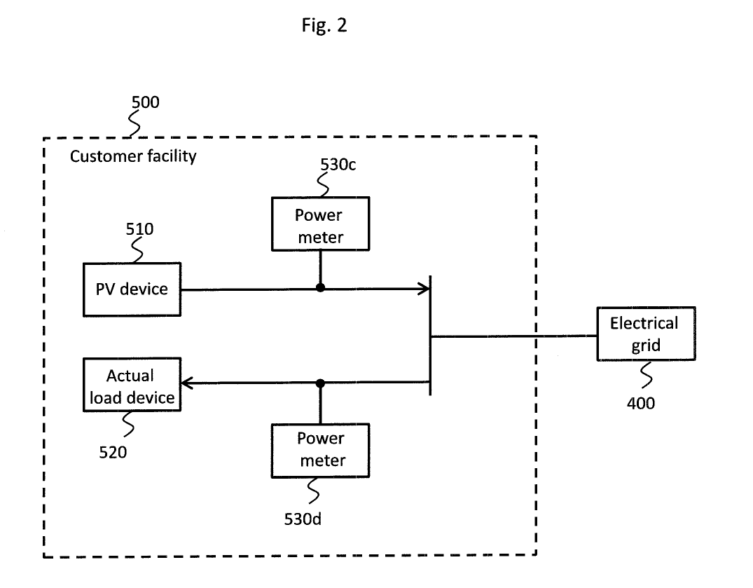

FIG. 2 shows a wiring method B. The wiring method B is a wiring method for separately measuring the PV power generation amount and the actual load. A power meter 530c measures the power generation amount of the PV device 510. A power meter 530d measures the amount of power from the electrical grid 400 and consumed by the actual load device 520. This wiring method is preferably employed to measure the PV power generation amount and the actual load, for the full amount purchase system of the PV power generation amount. However, in the current situation, many AMIs transmit the purchasing power amount and the selling power amount to the management server 410 while being connected through the wiring method A.

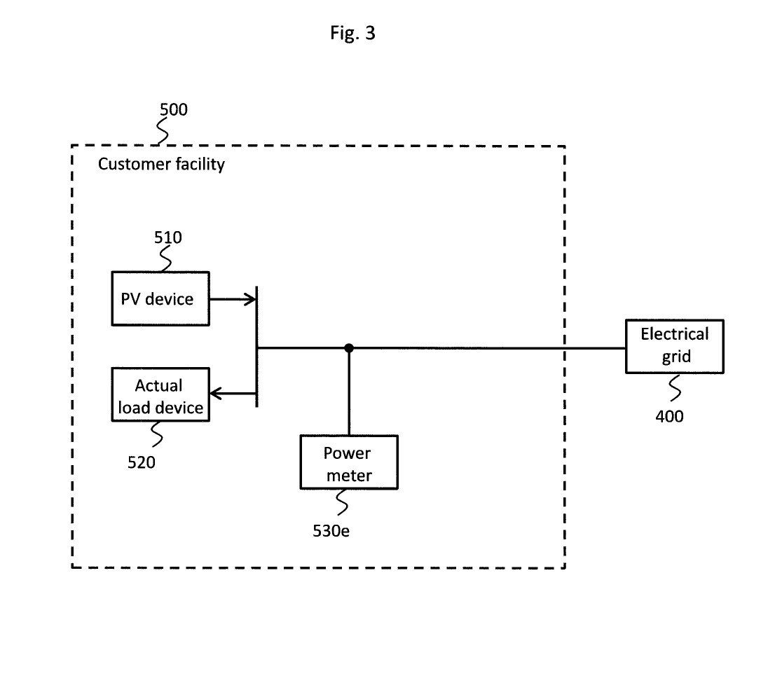

FIG. 3 shows a wiring method C. The wiring method is a wiring method for a conventional power meter 530e. The power meter 530e cannot measure the PV power generation amount and the actual load. Here, the power monitoring apparatus 101 may acquire the measured amount from the power meter 530e.

<<Input and Output to and from Power Monitoring Apparatus 101>>

Inputs and outputs to and from the power monitoring apparatus 101 are described below.

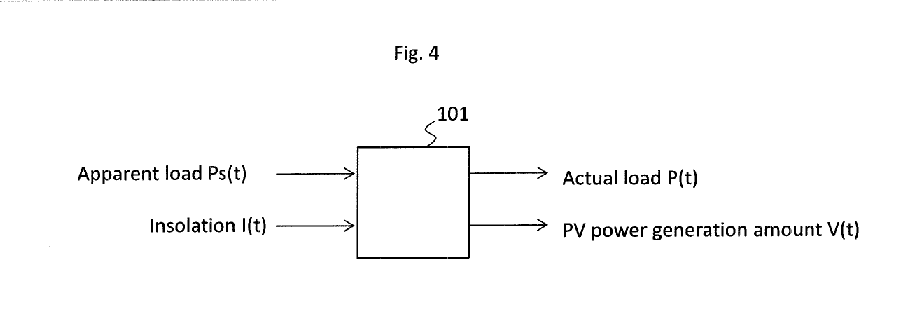

FIG. 4 shows inputs and outputs to and from the power monitoring apparatus 101 according to Example 1. In the description below, P(t), Ps(t), I(t), V(t), and K(t) respectively represent the actual load, the apparent load, the insolation, the PV power generation amount, and a PV device characteristic. The variables are discrete time series signals that change as time t elapses. K(t) is a function for converting the insolation on the surface of the PV panel 511 into the PV power generation amount. K(t) has a characteristic as a combination of a capacity and an efficiency of the PV device 510, as well as an elevation, an azimuth, and a temperature coefficient of the PV panel 511. When these characteristics can be measured, K(t) can be calculated. However, in many cases these characteristics are difficult to measure. In the description below, it is regarded that there is no short term change in the characteristics, and K is handled as an unknown constant. If required, K(t) that changes over time may be used.

The inputs to the power monitoring apparatus 101 are the apparent load Ps(t) of the customer facility 500 and the insolation I(t) on the PV device 510 of the customer facility 500. The outputs are the PV power generation amount V(t) and the actual load P(t). Here, the PV power generation amount V(t) is a result of multiplying the insolation I(t) by the PV device characteristic K as in the following formula.

V(t)=I(t)·K (E1)

Thus, the PV power generation amount V(t) is proportional to the insolation I(t), and is a proportionality constant of the proportionality. The apparent load Ps(t) is a result of subtracting the PV power generation amount V(t) from the actual load P(t) as in the following formula.

$$\begin{matrix}Ps ( t ) = P ( t ) - V ( t ) \\ = P ( t ) - I ( t ) \cdot K\end{matrix} \qquad ( E 2 )$$

How the input and output to and from the customer facility 500 are described is not limited to the model described above, and the following perspectives V1 to V5 may be taken into account.

(V1) When there are two types of the measurement value of the power amount obtained by the AMI in the customer facility 500, which are selling power amount measured by the power meter 530a and the purchasing power amount measured by the power meter 530b, the apparent load Ps(t) is described as (purchasing amount—selling amount).

(V2) A method where the power amount is separately described as active power and reactive power is available. The power amount can easily be converted into the active power and the reactive power by taking into account a power factor. Thus, in the description below, the relationship between the active power and the reactive power is omitted.

(V3) In this embodiment, the PV device characteristic is regarded as a linear characteristic. Still, for example, the PV power generation amount V(t) is affected by semiconductor characteristics of the PV panel 511, operating characteristic of the PCS 512, and the like. The PCS 512 operates based on a control algorithm stored therein, and thus the linearity may not necessarily be ensured. In the embodiments below, the PCS 512 is regarded as having the linear characteristic. However, if required, a non-linear characteristic may be added to the linear characteristic. For example, the non-linear characteristic may be achieved by conversion using a table, the non-linear characteristics may be achieved by using a function with higher powers, or a switch characteristic using a threshold value may be achieved.

(V4) In this embodiment, a signal changing over time is used as the time series signal. The time series signal may be measured at any interval. The power monitoring apparatus 101 acquires, as the time series signal, the power amount measured by a meter such as the AMI. The power monitoring apparatus 101 may acquire, as the time series signal, the power amounts measured in the same time period in a plurality of days. The sampling time interval may vary among types of the time series signal.

(V5) There are several types of insolation such as, for example, extraterrestrial insolation (insolation unaffected by the earth's atmosphere), a horizontal insolation (insolation on a horizontal surface, measured by the Meteorological Agency and the like), and a PV incident insolation (insolation on the PV panel 511 having an elevation and an azimuth). Conversion formulas for converting one of these types of insolation to the other have been known. In the description below, the PV incident insolation is used as the insolation, but may also be converted into the horizontal insolation to be used for example, by providing the conversion formula for a plurality of types of insolation described above to the PV device characteristic K. The management server 410 may store the measurement value of the insolation. The power monitoring apparatus 101 or the management server 410 may acquire the measurement value of the insolation from another server such as a server managing climate information.

<<Method for Estimating PV Power Generation Amount and Actual Load of Single Customer Facility 500>>

A method for estimating a PV power generation amount and an actual load of a single customer facility 500 will be described below.

The actual load P(t) largely depends on operating states of devices that are installed in the customer facility 500 and consume power. The operating state depends on the activities of a person residing in the customer facility 500, devices installed in the customer facility 500, climate, a type of day (distinguished as Saturday or Sunday), and the like. As described above, the actual load P(t) includes many fluctuation factors.

The major fluctuation factor of the insolation I(t) is the astronomical positional relationship between the sun and the earth. The formula for calculating the insolation I(t) is created based on a measurement values obtained in the past. Furthermore, the insolation I(t) on the ground surface involves a fluctuation factors such as, for example, a ratio between the direct insolation and dispersed insolation, and movement of clouds. The movement of clouds leads to blocking of solar radiation from the sun, and thus leads to a large difference. As described above, the insolation I(t) includes many fluctuation factors.

All things considered, it is appropriate to regard each of the actual load P(t) and the insolation value I(t) as an independently generated signal. The human activity is in a daily cycle, and thus the power consumption of the device may have characteristics in a daily cycle. Considering such characteristics, the signal may be limited within a time period shorter than a day to be regarded as being independent from each other. The actual load P(t) and the insolation I(t) being signals that are independent from each other, can be regarded as having no correlation in terms of statistics. The length of the time period of the time series signal is set in such a manner that the correlation between the time series signals input to the power monitoring apparatus 101 is eliminated. For example, the minimum length of the time period is set to be equal to or longer than time including at least two measurement intervals. The maximum length of the time period may be variably set by referring to the hours of sunlight within a day, which change in accordance with seasons, or an observation result of actual insolation. The length may be variably set by referring to a measurement interval, since the number of data pieces required for calculating the correlation may be obtainable in a short period of time when the measurement interval is short. Both of the lengths may be determined based on the experiment result using measurement data.

The method for estimating the PV power generation amount and the actual load in this embodiment is based on the absence of correlation between the two time series signal of the actual load P(t) and the insolation I(t). Thus, in the formula for calculating the correlation coefficient of the two time series signals, the correlation is regarded as being sufficiently small (no correlation). Thus, the unknown quantity in the formula is obtained. The unknown quantity is the PV device characteristic K for converting the insolation I(t) into the PV power generation amount V(t). By obtaining the PV device characteristic K, the PV power generation amount V(t) can be obtained from the insolation I(t) that has been known, and the actual load P(t) can be further obtained.

Here, R(·) represents the function for obtaining the correlation coefficient, and r represents the value of the correlation coefficient calculated therewith. The time period of the time series signal used for calculating the correlation coefficient r is referred to as a target time period. The description R(X, Y) represents a case where the correlation coefficient r is obtained for two variables X and Y. Specifically, r is obtained by the following formula where X(t) and Y(t) represent the discrete signals and I represents accumulation over the target time period.

$$\begin{matrix}r = R ( X , Y ) \\ = Σ ( ( X ( t ) - μ x ) \cdot ( Y ( t ) - μ y ) )\end{matrix} \qquad ( E3 )$$

By expanding the formula described above, the following formulae can be obtained, where t1, t2, . . . represent discrete time t.

$$\begin{matrix}r = R ( X , Y ) \\ = ( X ( t 1 ) - μ x ) \cdot ( Y ( t 1 ) - μ y ) + \\ ( X ( t 2 ) - μ x ) \cdot ( Y ( t 2 ) - μ y ) + …\end{matrix} \qquad ( E 4 )$$

In the formulae, μx represents an average of X(t) in the target time period, and μy represents an average of Y(t) in the target time period.

As described later, in the estimation method of this embodiment, the correlation coefficient r is not calculated from the time series signal by using R(·), but the variable included in R(·) is obtained with the value of the correlation coefficient r given in advance. In the description below, R(·) is described as R(Z) when the variable included in R(·) is Z to show the variable.

A case where a single customer facility 500 is the target is described below.

In the estimation method of this embodiment, the characteristic that the actual load P(t) and the insolation I(t) in the target time period have no correlation is used to separate the actual load P(t) and the insolation I(t) from each other. Thus, r is obtained by the following formula where R(·) is the formula for calculating the correlation coefficient r, and the actual load P(t) and the insolation I(t) are variables.

$$\begin{matrix}r = R ( \cdot ) \\ = R ( P ( t ) , I ( t ) )\end{matrix} \qquad ( E 5 )$$

Here, the actual load P(t) is obtained by the following formula from Formula E2 described above.

$$\begin{matrix}P ( t ) = Ps ( t ) + V ( t ) \\ = Ps ( t ) + I ( t ) \cdot K\end{matrix} \qquad ( E 6 )$$

The following formula is obtained by substituting the function into Formula E5.

r=R(Ps(t)+I(t)·K, I(t)) (E7)

Specifically, the following formula is obtained by using Formula E3.

r=Σ((Ps(t)+I(t)·K−μx)·(I(t)−μy)) (E8)

In the formula, μx represents the average of (Ps(t)+I(t)·K) over the target time period, μy represents the average of I(t) over the target time period, and Σ represents an accumulation over the target time period. When the apparent load Ps(t), the insolation I(t), and the average values μx and μy are substituted with data acquired as a measurement value, R(·) becomes a function R(K) with K being the variable.

r=R(K) (E9)

Here, in this invention, the PV device characteristic K is calculated with r being sufficiently small, that is with r=0 for example. As shown in Formula E8, R(·) is a linear function of K, and thus the solution of K is uniquely determined by Formula E9. The method for calculating the PV device characteristic K is not particularly limited, and an analytical method or an empirical method may be used. When the analytical method is used, the solution may be obtained with r=0. Alternatively, when the empirical method is used, a magnitude of r may be determined to be sufficiently small through comparison with a sufficiently small prepared threshold, without using r=0 as the condition of the solution. When the PV device characteristic K is thus determined, the PV power generation amount V(t) is determined by the following formula.

V(t)=I(t)·K (E10)

The actual load P(t) can be obtained by the following formula.

P(t)=Ps(t)−V(t) (E11)

With the estimation method described above, the actual load and the PV power generation amount can be separated from each other by using the apparent load in a single customer facility 500.

<<Configuration of Power Monitoring Apparatus 101>>

A configuration of the power monitoring apparatus 101 will be described below.

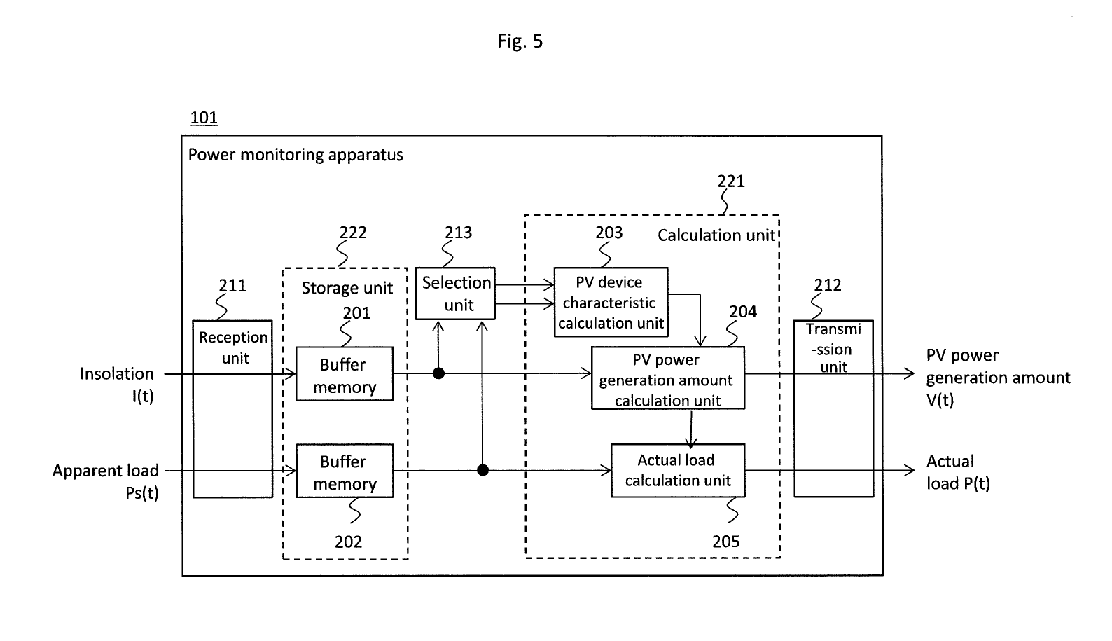

FIG. 5 shows the configuration of the power monitoring apparatus 101. The power monitoring apparatus 101 monitors a single customer facility 500, and uses the apparent load Ps(t) and the insolation I(t) as inputs, and outputs the actual load P(t) and the PV power generation amount V(t). The power monitoring apparatus 101 includes a reception unit 211, a transmission unit 212, a selection unit 213, a calculation unit 221, and a storage unit 222. The storage unit 222 is a storage device such as a memory, and includes a buffer memory 201 and a buffer memory 202. The calculation unit 221 includes a PV device characteristic calculation unit 203, a PV power generation amount calculation unit 204, and an actual load calculation unit 205.

The reception unit 211 is, for example, an interface for communicating with the power meters 530a and 530b. The reception unit 211 receives the measurement value of the selling power amount and the measurement value of the purchasing power amount respectively from the power meters 530a and 530b. The reception unit 211 calculates (purchasing power amount—selling power amount) as the apparent load Ps(t), and writes the result to the buffer memory 201. The reception unit 211 receives the measurement value of the insolation I(t) from a database such as the management server 410 that stores the insolation I(t), and writes the measurement value to the buffer memory 202. The reception unit 211 may receive the apparent load Ps(t) and the insolation I(t) from an energy management system such as a computer or HEMS (Home Energy Management System) provided in the customer facility 500. Specifically, the buffer memory 201 stores the time series signal of the apparent load Ps(t) and the buffer memory 202 stores the time series signal of the insolation I(t).

The reception unit 211 may receive the time series signal of the insolation I(t) from an insolation sensor that measures the change of the insolation over time. The insolation sensor measures the insolation at a predetermined time interval.

The buffer memory 201 stores the insolation I(t) input thereto. The buffer memory 202 stores the apparent load Ps(t) input thereto.

The selection unit 213 selects a sample used for the calculation from the samples of the time series signals of the apparent load Ps(t) and the insolation I(t), and stores the sample.

The PV device characteristic calculation unit 203 acquires the apparent load Ps(t) from the selection unit 213, acquires the insolation I(t) from the selection unit 213, and calculates the PV device characteristic K based on the apparent load Ps(t) and the insolation I(t).

The PV power generation amount calculation unit 204 reads the insolation I(t) from the buffer memory 201, and calculates the calculated PV device characteristic K and the PV power generation amount V(t). The actual load calculation unit 205 reads the apparent load Ps(t) from the buffer memory 202, and calculates the actual load P(t) based on the PV power generation amount V(t) and the insolation I(t).

The transmission unit 212 is, for example, a communication interface connected to the communication network 420. The transmission unit 212 transmits the PV power generation amount V(t) and the actual load P(t) thus calculated to an energy management system or a management apparatus such as the management server 410.

<<Monitoring processing>>

Monitoring processing is described below. In the monitoring processing, the power monitoring apparatus 101 repeats the estimation of the PV power generation amount V(t) and the actual load P(t) over a long period of time.

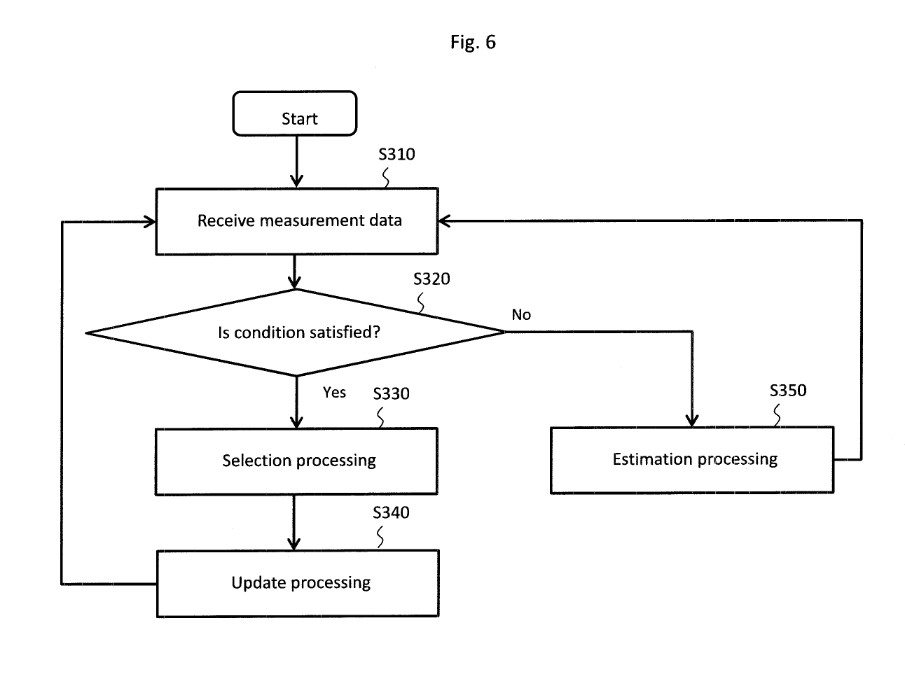

FIG. 6 shows the monitoring processing.

First of all, in S310, the reception unit 211 receives the apparent load Ps(t) from the power meters 530a and 530b and stores the apparent load Ps(t) in the buffer memory 201. Furthermore, the reception unit 211 receives the insolation I(t) from the management server 410 and stores the insolation I(t) in the buffer memory 202.

Then, in S320, the PV device characteristic calculation unit 203 determines whether a condition set in advance is satisfied. For example, the PV device characteristic calculation unit 203 determines that the condition is satisfied, in a case where the power monitoring apparatus 101 is initialized, in a case where a predetermined holding time (about a week) has elapsed, in a case where the time has reached a point where a season changes set in advance, in a case where the insolation largely fluctuates, in a case where an instruction to update the PV device characteristic K has been received from outside, or the like. The conditions serve as a trigger for the calculation of the PV device characteristic K.

The factors that change the PV device characteristic K are temperature change, aging degradation, and contamination of the surface of the PV panel 511. Thus, the change of the PV device characteristic K is of a slight level, and takes much longer time than the measurement interval of the measurement values of the power amount and the insolation. The device characteristics may be calibrated if required.

When the result of S320 is Yes, the PV device characteristic calculation unit 203 advances the processing to S330.

In S330, the selection unit 213 performs selection processing of selecting the time series signals of the apparent load Ps(t) and the insolation I(t).

Then, in S340, the PV device characteristic calculation unit 203 performs updating processing of calculating and updating the PV device characteristic K, and advances the processing to S310.

When the result of S320 is No, the PV device characteristic calculation unit 203 advances the processing to S350.

In S350, the PV device characteristic calculation unit 203, the PV power generation amount calculation unit 204, and the actual load calculation unit 205 perform estimation processing of estimating the PV power generation amount V(t) and the actual load P(t) by using the PV device characteristic K, and advances the processing to S310.

The monitoring processing is as described above.

Through the monitoring processing, the PV power generation amount V(t) and the actual load P(t) are repeatedly estimated.

<<Selection Processing>>

The selection processing described above is described below in detail.

The PV device characteristic calculation unit 203 handles the apparent load Ps(t) and the insolation (t) as the time series signals, and performs the calculation based on the nature of the correlation coefficient (no correlation). Generally, the length of the time series signal to be used in the calculation is preferably longer to achieve a higher accuracy of the correlation coefficient to be calculated. The time period of the time series signal is preferably a time period where the time series signal largely changes. The sampling interval of the time series signal is preferably short as much as possible. Even when the length of the time series signal is short, a favorable result may be obtained when the change of the time series signal is sufficiently large. As described above, the selected time period has many options. The continuity in terms of time between samples of the time series signal is not a required condition, and the samples may be discontinuous in terms of time. In other words, the time series signals may be joined together as desired (to achieve higher accuracy) to calculate the correlation coefficient (no correlation). Preferably, the time period where the insolation largely fluctuates due the movement of clouds is preferably selected to acquire the time series signal used for calculating the correlation coefficient. Here, the PV device characteristic calculation unit 203 selects the time period where the insolation largely fluctuates. Thus, a sample of the time period where the insolation largely fluctuates can be extracted from the time series signals of the apparent load Ps(t) and the insolation I(t). Here, the period during which the fluctuation of the insolation is measured may be days. The PV device characteristic calculation unit 203 may join the extracted samples together to create the time series signals of the apparent load Ps(t) and the insolation I(t). This procedure may also be used as a data complementary method in a case where lack of measure data has occurred.

When the reception unit 211 receives the change of insolation over time from the insolation sensor, the insolation sensor may measure relative change of insolation over time. Thus, the insolation sensor may not necessarily measure the PV incident insolation.

A specific example of the selection processing is described below.

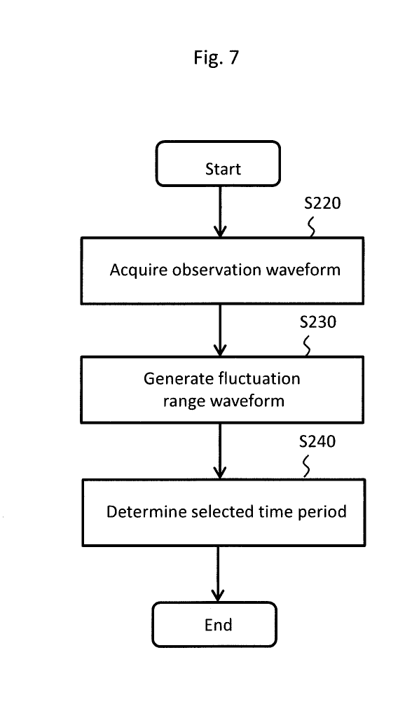

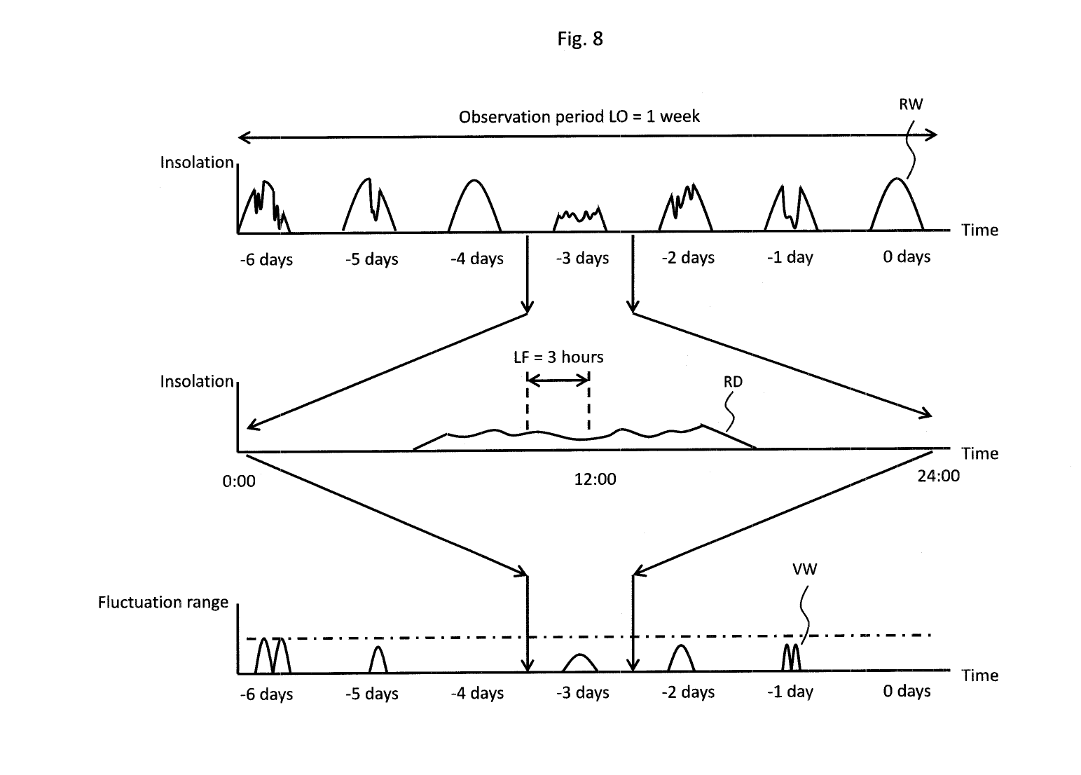

FIG. 7 shows the selection processing, and FIG. 8 shows a signal used in the selection processing. First of all, in S220, the selection unit 213 acquires an observation signal RO indicating the change of insolation over time. In this specific example, the observation signal RO of the insolation, an enlarged waveform RD, and a fluctuation range signal VW are shown.

Regarding the observation signal RW, the horizontal axis presents time and the vertical axis represents the measurement value of the insolation. The time of the observation signal RW is described with the time of the latest observation result being 0. An observation period LO as the length of the observation signal RW is set in advance and is, for example, a week. In some days, a short term insolation change is found, due to the reduction of insolation caused by the movement of clouds.

Next, in S230, the selection unit 213 generates the fluctuation range signal VW of the observation signal RW through fluctuation range calculation processing. The fluctuation range calculation processing uses the observation signal RW within a time window as an input, and outputs the magnitude of the change of the input. The enlarged waveform RD is a waveform obtained by enlarging the time axis of the observation signal RO within a single day. The length LF of the time window in the fluctuation range calculation processing is illustrated above the enlarged waveform RD. The length LF of the time window is a period including no change of insolation over a day. The length LF of the time window is determined in such a manner that the time window includes a plurality of measurement times for the observation signal RW. For example, the measurement interval of the observation signal RW is set to 30 minutes, the length of the time window is set to three hours, and the measurement times at both ends are included in the time window.

Now, three specific examples of the fluctuation range calculation processing are described.

In first fluctuation range calculation processing, the signal characteristic is determined from a frequency component included in the time series signal. For example, regarding the insolation, the sunrise and the sunset are in a daily cycle. Regarding the actual load, the human activity includes a component in a cycle of a day and further includes various shorter period components. It is regarded that in many cases, a load pattern of a household appliance depends on human activities. Thus, there may be cases where the time series signal can be separated into specific components with the frequency component. For example, a method such as Fourier conversion can be used for converting the time series signal into the frequency components. In the first fluctuation range calculation processing, for example, the selection unit 213 calculates as the fluctuation range, the magnitude of the frequency component of a specific frequency for a measurement value of the insolation within a time window.

In second fluctuation range calculation processing, a frequency distribution as a histogram of the magnitude of the time series signal is used. The histogram has a characteristic that a frequency of a specific measurement value is high when the change in the time series signal is small. When the time series signal randomly changes, the measurement values are uniformly distributed. If the frequency distribution range of the measurement value of the insolation within a time width is wide, the change of the insolation is large. On the other hand, when the frequency distribution range is narrow, the change of insolation is small. In the second fluctuation range calculation processing, the selection unit 213 calculates as the fluctuation range, the frequency distribution range which is equal to or large than a threshold of the frequency set in advance from the measurement value of the insolation within the time window. The width of the frequency distribution may be a half value width.

In third fluctuation range calculation processing, the magnitude of the change is determined by using dispersion or a standard deviation of the time series signal. The dispersion is obtained by dividing the sum of the squares of the differences from the average value by the number of measurement points. A larger dispersion of the time series signal leads to a larger calculated distribution value. In the second fluctuation range calculation processing, for example, the selection unit 213 calculates as the fluctuation range, the dispersion of the measurement values of the insolation within the time window.

The selection unit 213 may binarize the fluctuation range by determining the magnitude of the fluctuation range by using the threshold of the fluctuation range set in advance. The threshold of the fluctuation range depends on the objective of the determination, a method of signal processing to be used, and a nature of a signal as a target, and may be determined through experiments.

Here, the selection unit 213 generates the fluctuation range signal VW representing the change of the fluctuation range over time by repeating fluctuation range calculation processing of calculating the fluctuation range at each time period of the length LF of the time period set by shifting the time window every 30 minutes as the measurement interval. Regarding the fluctuation range signal VW, the horizontal axis represents the time of each time period, and the vertical axis represents the fluctuation range. A method of quantifying the magnitude of the fluctuation of the insolation is not limited to that in this embodiment.

Next, in S240, the selection unit 213 selects as the selected time period, and terminates the flow, a time period with the largest fluctuation range from all the time periods within the observation period LO. Specifically, the selection unit 213 selects the selected time period from all the time periods within the observation period LO, based on the magnitude of the fluctuation of the insolation signal within each of the time periods.

The PV device characteristic calculation unit 203 uses the measurement values of the apparent load Ps(t) and the insolation I(t) in the selection time period to calculate the PV device characteristic K. When it continues raining during the observation period, the time period with the maximum fluctuation range can be obtained but the selection unit 213 does not output the selected time period because the fluctuation range thereof is small. Here, the PV device characteristic calculation unit 203 preferably keeps using the previously obtained PV device characteristic K. The selection unit 213 may calculate and store a reference fluctuation range based on the fluctuation range calculated by the previous fluctuation range calculation processing, and may not output the selected time period when the fluctuation range calculated through the latest fluctuation range calculation processing is smaller than the reference. In this case, the PV device characteristic calculation unit 203 does not update the PV device characteristic K.

The selection unit 213 may select as the selected time periods, a predetermined number of time periods with the highest fluctuation ranges from all the time periods. Here, the selection unit 213 may join the selected predetermined number of time periods together to create the time series signal of a predetermined length suitable for calculating the correlation coefficient.

The selection processing is as described above.

With the selection processing described above, the accuracy of the PV device characteristic K can be improved by using the time series signal of the time period with a large isolation fluctuation.

In the selection processing, the selection unit 213 may perform filter processing for the observation signal RW in the selection processing. By shortening the sampling period of the target time series signal, the time series signal including high frequency components can be obtained. With the high frequency component included, the change overtime can be separated in detail, and thus in many cases, favorable signal characteristic can be obtained. For example, the insolation might fluctuate every few seconds due to the movement of clouds, and thus the sampling at a period that is equal to or less than half the length of the period of change is preferably employed to capture the change. Generally, a theory involved in the data collection is known as sampling theorem. However, the time series signal as the measurement value might include time deviation. For example, some pyrheliometers have a measurement principle that the insolation is subjected to heat conversion and then the temperature is measured. The measurement value of such a pyrheliometer has a response delay compared with the actual insolation fluctuation. The response delay is also produced by an individual difference between models and devices. Such a delay in response time is equivalent to the lack of high frequency component. When the correlation coefficient is calculated by using such a measurement value, the high frequency component as the calculation result includes errors.

To reduce the errors, filter processing of providing a certain frequency characteristic to the measurement value is preferably performed. To solve the problem of the delay in the response time in particular, a characteristic of reducing the higher frequency component, that is, a characteristic of passing lower frequency components is preferably used. For example, in the filter processing, convolution integration is performed by using a weight coefficient within a time window. Alternatively, the measurement values may be accumulated or averaged within the time window. This is equivalent to outputting, by the AMI described above, a signal obtained by accumulating the values of power at 30 minutes interval. As described above, when a plurality of time series signals are calculated to calculate the correlation coefficient, the frequency characteristics of the time series signals are preferably approximated in advance. To achieve this, the selection unit 213 may adjust the frequency characteristics of the measurement values through the filter processing.

<<Update Processing>>

The update processing described above is described in detail below.

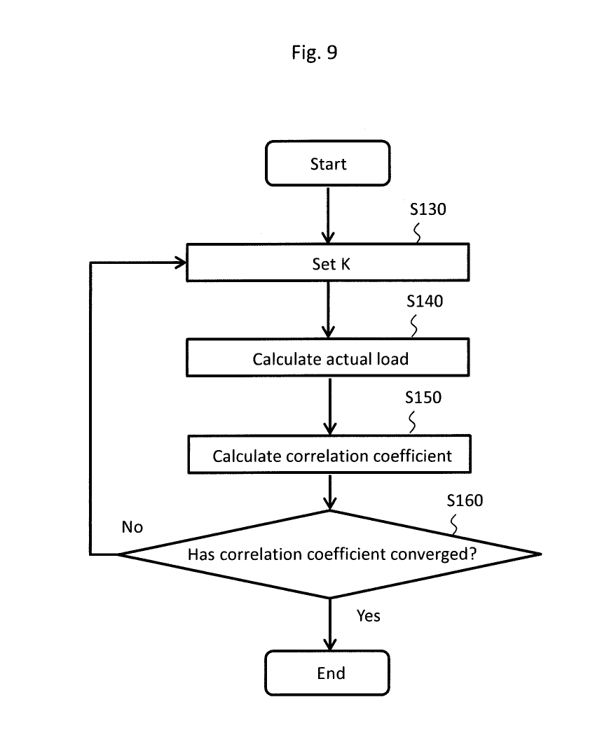

FIG. 9 shows the update processing. In the update processing, the PV device characteristic K is obtained through repetitive calculations involving convergence determination. The update processing is not limited to this example, and it is a matter of course that a certain method for achieving higher speed and higher accuracy may be additionally employed.

The PV device characteristic calculation unit 203 calculates the PV device characteristic K by using the time series signal selected by the selection processing. S130 to S160 form a processing loop.

First of all, in S130, the PV device characteristic calculation unit 203 sets the PV device characteristic K. Here, for example, the PV device characteristic calculation unit 203 sets the PV device characteristic K to an initial value set in advance, in S130 performed for the first time in the processing loop. Then, in S130 performed for the second time and after, a step stored in advance is added to the PV device characteristic K.

Then, in S140, the PV device characteristic calculation unit 203 calculates the actual load P(t) from Formula E6, based on the apparent load Ps(t), the insolation I(t), and the PV device characteristic K.

Next in S150, the PV device characteristic calculation unit 203 calculates the correlation coefficient r from Formula E5, based on the actual load P(t) and the insolation I(t).

Next, in S160, the PV device characteristic calculation unit 203 determines whether the correlation coefficient r has converged. The PV device characteristic calculation unit 203 determines that the correlation coefficient r has converged when, for example, the magnitude of the correlation coefficient r is equal to or smaller than a threshold set in advance. Specifically, it is determined that there is no correlation between the actual load P(t) and the insolation I(t). The magnitude of the correlation coefficient r is, for example, an absolute value of the correlation coefficient r.

When the result of S160 is No, that is, when it is determined that the correlation coefficient r has not converged, the PV device characteristic calculation unit 203 advances the processing to S130.

When the result of S160 is yes, that is, when it is determined that the correlation coefficient r has converged, the PV device characteristic calculation unit 203 terminates the flow.

The update processing is as described above.

The PV device characteristic calculation unit 203 stores the PV device characteristic K thus calculated in a memory during the observation period. The PV power generation amount calculation unit 204 and the actual load calculation unit 205 respectively calculates the PV power generation amount V(t) and the actual load P(t) during the observation period by using the stored PV device characteristic K.

With the update processing, the PV device characteristic K can be calculated under the condition that the actual load P(t) and the insolation I(t) are not correlated.

For example, the PV device characteristic calculation unit 203 may detect the change of season and recalculate the PV device characteristic K. Thus, the fluctuation due to a season is reflected in the PV device characteristic K, whereby the PV power generation amount V(t) and the actual load P(t) can be calculated with a higher accuracy.

<<Estimation Processing>>

The estimation processing described above is described below in detail.

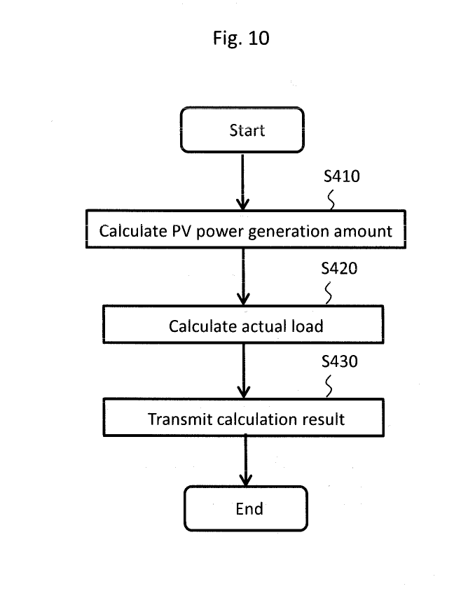

FIG. 10 shows the estimation processing. First of all, in S410, the PV power generation amount calculation unit 204 calculates the PV power generation amount V(t) from Formula E10, based on the PV device characteristic K and the insolation I(t) in the buffer memory 201.

Next, in S420, the actual load calculation unit 205 calculates the actual load P(t) from Formula E11, based on the PV device characteristic K and the apparent load Ps(t) in the buffer memory 202.

Next, in S430, the transmission unit 212 transmits the PV power generation amount V(t) and the actual load P(t) as the calculation results to the management server 410. The PV power generation amount calculation unit 204 and the actual load calculation unit 205 may respectively write the PV power generation amount V(t) and the actual load P(t) to the memory, and the transmission unit 212 may periodically transmit the PV power generation amount V(t) and the actual load P(t) to the management server 410.

The estimation processing is as described above.

With the estimation processing, the apparent load Ps(t) can be separated into the PV power generation amount V(t) and the actual load P(t).

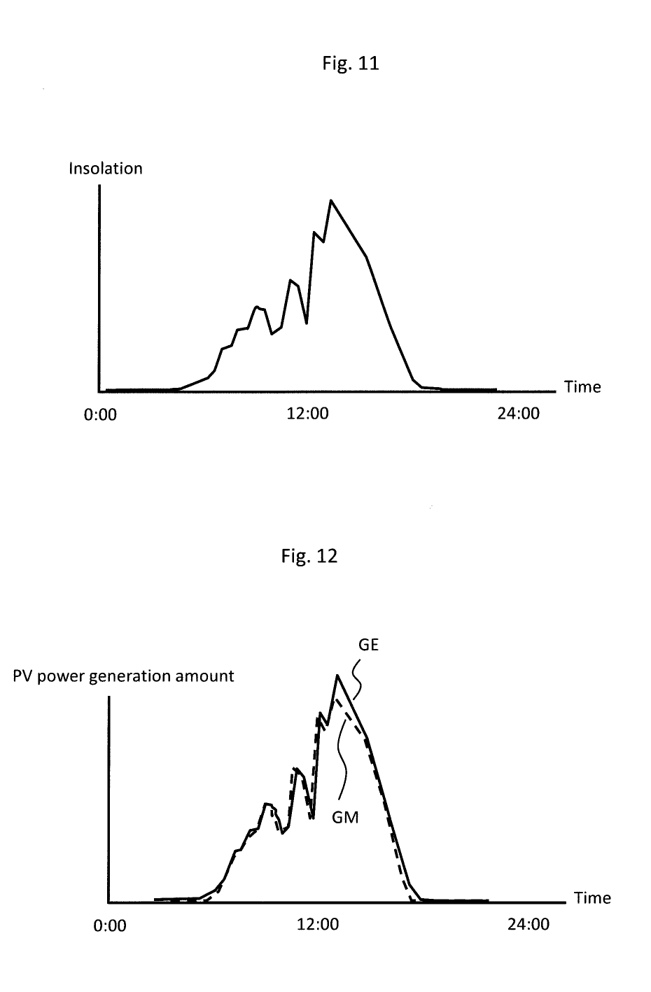

FIG. 11 shows the insolation I(t). The horizontal axis in the figure represents the time t and the vertical axis represents the insolation I(t). The figure shows the insolation I(t) within a day. The power monitoring apparatus 101 acquires the insolation I(t) from the management server 410 or the insolation sensor.

FIG. 12 shows the PV power generation amount. The figure shows a measured value GM of the PV power generation amount and an estimated value GE of the PV power generation amount estimated through the estimation processing described above. The estimated value GE is plotted almost the same as the measured value GM but is slightly different therefrom around the peak. The difference is caused by the non-linear characteristics of the PV device 510 such as the drop in the efficiency due to the temperature rise of the PV panel 511 and the output regulation by the PCS 512.

Means for measuring the apparent load Ps(t) of the customer facility 500 is not limited to that in this embodiment. Here, the accuracy of the calculated PV device characteristic K can be effectively improved by shortening the time interval between measurement values of the power amount and the insolation. In other words, providing higher frequency components in the measurement value is effective. Thus, a power meter with a variable sample interval by which the sample interval of the power meter can be shortened as desired is used for the time period used for calculating the PV device characteristic K. As a result, highly accurate calculation can be performed.

The PV device characteristic K is a coefficient for converting the insolation I(t) into the PV power generation amount V(t). The insolation herein is a PV incident insolation on the PV device 510, and is of a value different from the horizontal insolation measured by the Meteorological Agency. It has been known that the horizontal insolation can be converted into the PV incident insolation through angular conversion based on the elevation and the azimuth of the PV panel 511. In this embodiment, the calculation of the PV device characteristic K may include the effect corresponding to the angular conversion described above. The PV device characteristic K may further include the characteristics of the PV device 510 such as power generation capacity and efficiency. This means that the PV device characteristic K needs not to be known in advance, and the insolation I(t) may be in any unit. Therefore, highly practical advantage can be obtained.

The measurement unit of the insolation is described, for example, as kWh·m⁻² (kW per hour and per square meter) by using J (joule) or W (watt). When the measurement interval is 1 second (1 sec), the unit is kWs·m⁻². To actually measure the insolation, the type, accuracy, time response, and the like of the pyrheliometer as the meter need to be examined in advance, and furthermore, purchasing, installing, and maintenance costs are required. In this embodiment, the insolation may be in any unit, and thus any appropriate alternative signal value can be used. The insolation sensor can use an output signal of a sensor related to a brightness of a certain kind. The insolation sensor includes an illumination sensor (lux or any other unit may be employed) provided in the customer facility 500, a camera (any unit may be employed) such as a monitoring camera, and the like. Thus, the PV incident insolation itself needs not to be measured. The time interval for measuring the signal corresponding to the insolation may be a measurement interval of the AMI (30 minutes or 15 minutes for example). The power monitoring apparatus 101 may acquire the hours of sunlight from weather data announced by the Meteorological Agency, calculate the insolation during clear weather through a known method, and combine the results to generate the signal corresponding to the insolation. If the power monitoring apparatus 101 can acquire the power generation amount of an adjacent PV device 510, the power monitoring apparatus 101 can use the PV power generation amount instead of the insulation.

For example, in the procedure ST2 described above, even when the ICA is applied to a plurality of adjacent feeder sections, the solution cannot be obtained only from information on a single feeder section.

In this embodiment, the PV power generation amount and the actual load can be separated from each other from the solar radiation amount and the apparent load of a single customer facility 500.

The power monitoring apparatus 101 may be provided outside the customer facility 500, and may be provided in the management server 410 and the like. In this case, the power monitoring apparatus 101 is coupled to the power meters 530a and 530b in each customer facility 500, and acquires the measurement values of the power amount from the power meters 530a and 530b, through the communication network 420.

The power monitoring apparatus 101 may be implemented by a computer. The computer includes a microprocessor such as a CPU (Central Processing Unit) and a memory that stores a program. The program causes the microprocessor to function as the PV device characteristic calculation unit 203, the PV power generation amount calculation unit 204, and the actual load calculation unit 205.

### EXAMPLE 2

In this embodiment, a power monitoring system is described that estimates the PV power generation amounts and the actual loads of a plurality of customer facilities 500.

<<Configuration of Power Monitoring System>>

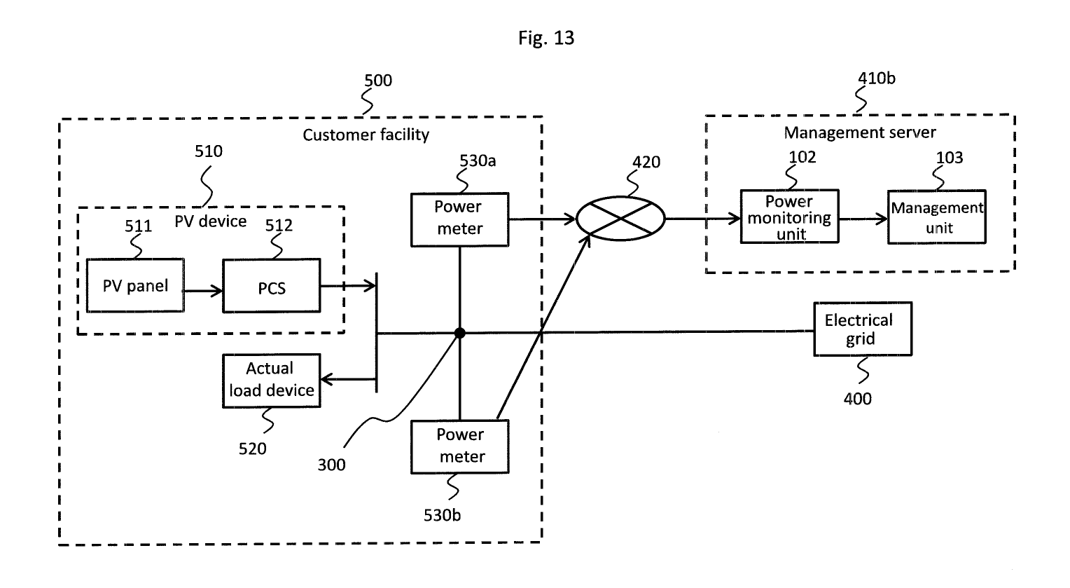

FIG. 13 shows a configuration of the power monitoring system according to Example 2. The power monitoring system of this embodiment is different from Example 1 in that a management server 410b is provided instead of the power monitoring apparatus 101 and the management server 410. The management server 410 includes a power monitoring unit 102 and a management unit 103. The power monitoring unit 102 is an application example of the power monitoring apparatus of this invention. The management unit 103 manages the power amount measured in the customer facility 500, as is the case of the management server 410 of Example 1. The power monitoring unit 102 acquires the selling power amount and purchasing power amount respectively from the power meters 530a and 530b through the communication network 420.

<<Method for Estimating PV Power Generation Amounts and Actual Loads of Two Customer Facilities>>

The method for estimating the actual loads and the PV power generation amounts of two customer facilities 500 is described below.

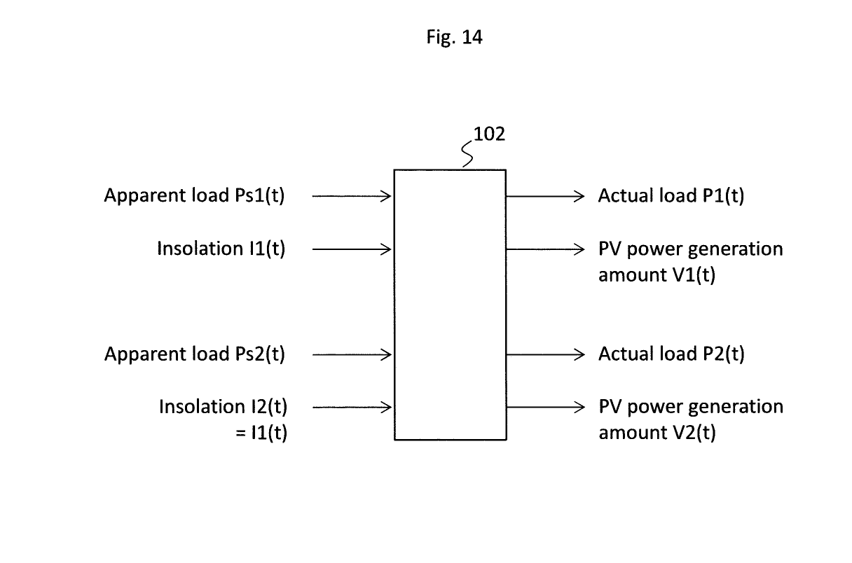

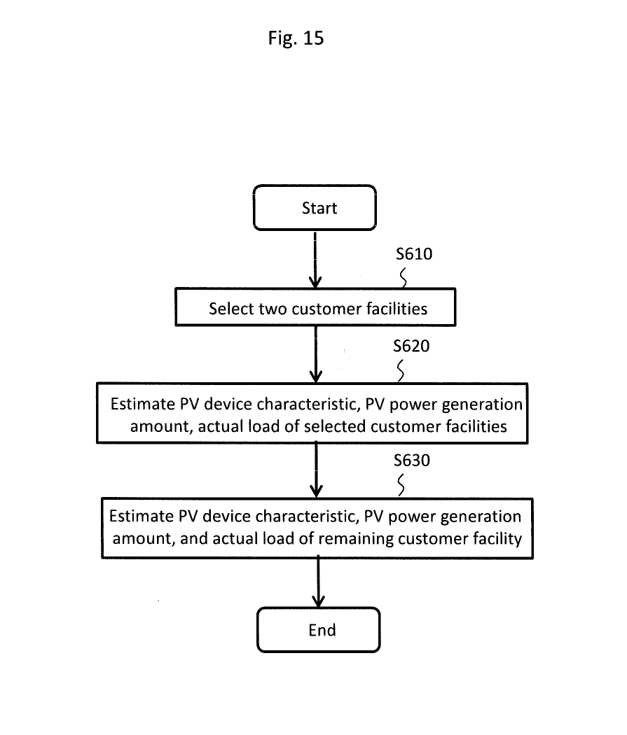

FIG. 14 shows inputs and outputs to and from the power monitoring unit 102 according to Example 2. In the description below, the two customer facilities 500 are distinguished from each other, with reference numerals “1” and “2”, as the customer facility 500 of a first customer and the customer facility 500 of a second customer. Ps1(t) and Ps2(t) and I1(t) and I2(t) respectively represent the apparent loads and the insolation values as inputs to the power monitoring unit 102. P1(t) and P2(t) and V1(t) and V2(t) respectively represent the actual loads and the PV power generation amounts as the outputs from the power monitoring unit 102.

The non-correlated nature of the time series signals are applied to the two customer facilities 500. Thus, the PV power generation amounts and the actual loads of the two customer facilities 500 can be estimated. The relationship among the inputs and outputs to and from the two customer facilities 500 is described in the following formulae.

$$\begin{matrix}\begin{matrix}P 1 ( t ) = Ps 1 ( t ) + V 1 ( t ) \\ = Ps 1 ( t ) + I 1 ( t ) \cdot K 1\end{matrix} & ( E21 ) \\ \begin{matrix}P 2 ( t ) = Ps 2 ( t ) + V 2 ( t ) \\ = Ps 2 ( t ) + I 2 ( t ) \cdot K 2\end{matrix} & ( E 22 )\end{matrix}$$

As in the case of the single customer facility 500 in Example 1, the correlation r of the time series signals of the actual load and the insolation of each customer facility 500 is described in the following formula by using R(·). A specific formula in calculating the correlation r is described by the following formula in the same form as that for the single customer facility 500.

$$\begin{matrix}\begin{matrix}r = R ( P 1 ( t ) , I 1 ( t ) ) \\ = R ( Ps 1 ( t ) + I 1 ( t ) \cdot K 1 , I 1 ( t ) )\end{matrix} & ( E 23 ) \\ \begin{matrix}r = R ( P 2 ( t ) , I 2 ( t ) ) \\ = R ( Ps 2 ( t ) + I 2 ( t ) \cdot K 2 , I 2 ( t ) )\end{matrix} & ( E 24 )\end{matrix}$$

Here, the apparent loads Ps1(t) and Ps2(t) are obtained as measurement values. Thus, R(·) is a function including the insolation values I1(t) and I2(t) and PV device characteristic K1 and K2 as variables. The actual load P1(t) and the insolation I1(t) have no correlation (r=0). The actual load P2(t) and the insolation I2(t) have no correlation (r=0). Due to these facts, the PV device characteristic K1 and K2 are functions respectively including the insolation values I1(t) and I2(t) which are described in the following formulae.

K1=F1(I1(t)) (E25)

K2=F2(I2(t)) (E26)

Here, it is assumed that the two facilities are adjacent to each other, and the insolation values I1(t) and I2(t) are the same. Thus, Formulae E25 and E26 are merged and the insolation values I1(t) and I2(t) are eliminated, whereby K1 and K2 are associated with each other through constants k12 and k21.

K1/K2=k12 (E27)

K2/K1=k21 (E28)

The following formulae are obtained by rewriting P1(t) and P2(t) by using the constants k12 and k21.

P1(t)=Ps1(t)+(P2(t)−Ps2(t))·k12 (E29)

P2(t)=Ps2(t)+(P1(t)−Ps1(t))·k21 (E30)

When the two facilities consume power independently from each other, the actual loads P1(t) and P2(t) have no correlation. The following formula is obtained by using Formula R(·) for calculating the correlation coefficient.

$$\begin{matrix}r = R ( P 1 ( t ) , P 2 ( t ) ) \\ = R ( P 1 ( t ) , Ps 2 ( t ) + ( P 1 ( t ) - Ps 1 ( t ) ) \cdot k 21 )\end{matrix} \qquad ( E 31 )$$

In this formula, all values except for P1(t) are known, and thus R(·) is a function of P1(t) as described in the following formula.

r=R(P1(t))=0 (E32)

Thus, P1(t) satisfying the formula can be obtained as the solution. Similarly, P2(t) can be solved. In this estimation method, when P1(t) and P2(t) as well as the constants k12 and k21 are difficult to analytically obtain, a solution method based on a known numerical analysis may be employed. A method for the numerical analysis may be appropriately selected and used, and is not limited to a specific method.

The method for separating the PV power generation amount and the actual load from each other described above requires the conditions that: the insolation values of the two facilities can be regarded as being the same; the actual load and the insolation are independent from each other in each of the two facilities; the insolation (PV power generation amount) fluctuates by a certain level; and the actual loads of the two facilities are independent from each other. Under the conditions, the PV device characteristics, the PV power generation amounts, and the actual loads of the two facilities are calculated by using the insolation that is common to the two facilities.

<<Method for Estimating PV Power Generation Amount and Actual Load of a Plurality of Customer Facilities in Area>>

A method for estimating the PV power generation amounts and the actual loads of a plurality of customer facilities 500 in an area is described below.

When the insolation values respectively in the target customer facility 500 and an adjacent customer facility 500 are close to each other and the PV power generation amount of the customer facility 500 is obtained, the PV power generation amount of the adjacent customer facility 500 may be used instead of the insolation of the target customer facility 500. Thus, to calculate the PV power generation amount and the actual load, the insolation may not be used, and the alternative signal may be used. Thus, by using the PV power generation amount calculated for a certain customer facility 500 instead of the insolation for another customer facility 500, the PV power generation amounts and the actual loads of the remaining customer facilities 500 in the area can be calculated. In this manner, the actual loads and the PV power generation amounts of a plurality of customer facilities 500 can be calculated.

Area estimation processing for estimating the PV power generation amounts and the actual loads of a plurality of customer facilities 500 in an area is described below.

FIG. 16 shows the area estimation processing.

In S610, the power monitoring unit 102 selects two customer facilities 500 having the actual loads with low correlation from a plurality of customer facilities 500 in an area.

Next, in S620, the power monitoring unit 102 estimates the PV device characteristics, the PV power generation amounts, and the actual loads of the selected two facilities with the method for estimating the PV power generation amounts and the actual loads in the case where the number of facilities is two.

Next, in S630, the power monitoring unit 102 uses the PV power generation amount of one of the facilities in the calculation results in S620 instead of the insolation in the method for estimating the PV power generation amount and the actual load in the case where the number of facilities is one. Thus, the PV power generation amount and the actual load of each of the remaining customer facilities 500 are estimated.

The area estimating processing is as described above.

With the area estimating processing, the calculated PV power generation amount of the customer facility 500 is used in place of the insolation so that, without using the insolation of another customer facility 500, the PV device characteristic K, the PV power generation amount, and the actual load of the customer facility 500 can be calculated.

As in Example 1, the time series signals of the apparent load Ps(t) and the insolation I(t) may not be continuous in terms of time, and a signal obtained by coupling signals, in the time period where the signal largely fluctuates, with each other may be used. For example, when the insolation is common to any two customer facilities 500, the difference in the apparent load largely depends on the difference in the actual load. Thus, the correlation between the apparent loads of two facilities at an appropriate time unit is calculated and the time periods with low correlations are extracted and combined. As a result, a time series signal with a large fluctuation can be created. By executing the area estimation processing described above with the time series signal of the time period, an accurate calculation result can be obtained.

In the description above, the power monitoring apparatus 101 may be incorporated in the AMI. When the estimation values of the PV power generation amount and the actual load are transmitted instead of the measurement values of the selling and purchasing power amounts that are transmitted to the management server 410 such as the MDMS by a normal AMI, a transmission data amount does not increase. In this case, the management server 410 can acquire the estimation value required for implementing the full amount purchase system for the PV power generation amount from each customer facility 500. When the AMI includes means for appropriately changing a transmission interval for acquiring the estimation value, the transmission interval for the estimation value may set to be long to reduce the transmission data amount. For performing stabilization control for the electrical grid 400, the transmission interval for the estimation value may set to be short to achieve higher accuracy in the stabilization control. Here, the AMI may create a control signal for the transmission interval therein, or control the transmission interval based on an instruction from an upper level apparatus such as the management server 410.

In a configuration where the power monitoring apparatus 101 is incorporated in the AMI, the time interval for transmitting the estimation value and the time interval for the estimation processing for the PV power generation amount and the actual load may not be synchronized. Many AD (Analog/Digital) converters, used for the power meters 530a and 530b, can operate much faster compared with the transmission interval (for example 15 minutes or 30 minutes) of the measurement value of the AMI. In this case, the AMI may perform non-correlated signal processing by using the measurement value obtained by the sampling faster compared with the time interval for transmitting the estimation value. Faster sampling speed leads to a larger number of samples per unit time, whereby candidates of the time periods with a large change in the time series signal increases, and higher freedom of selection can be achieved. All things considered, with the non-correlation achieved with a higher accuracy, higher accuracy of the obtained PV device characteristic K can be expected. Alternatively, the time series signal of a shorter time period may be used to obtain the PV device characteristic K.

When the power monitoring unit 102 is incorporated in the management server 410b that collects the measurement value of the AMI, the management server 410b can perform centralized signal processing. Here, none of the apparent load Ps(t) and the insolation I(t) as the input time series signals and the actual load P(t) and the PV power generation amount V(t) as the output time series signals has a form of a signal line. The time series signals are input and output through data reading and writing by a storage apparatus in the management server 410b.

Control apparatuses such as CEMS (Community Energy Management System) dispersedly arranged at portions close to the customer facility 500 may include the power monitoring unit 102. For example, the control apparatus that performs voltage control or the like for the electrical grid 400 may perform signal processing such as the monitoring processing described above by partly using its calculation capacity. The control apparatus may use the insolation that can be commonly used in the area only within the area in a closed manner, and may only transit the estimation values of the PV power generation amount and the actual load to the management server 410 such as the MDMS.

In a similar manner, the power monitoring unit 102 can estimate the actual load and the PV power generation amount also for a plurality of customer facilities 500, or in a distribution grid such as a mega solar connected to the PV devices 510 in a large scale. For this estimation, the power amount obtained by combining the actual loads and the PV power generation amounts of a plurality of coupled customer facilities 500 in the distribution grid is used. The power amount is measured by the power amount sensor such as a switch with a sensor in the distribution grid for example.

When a plurality of customer facilities 500 connected to the distribution grid are positioned closely in a single area, the insolation values in the customer facilities 500 can be regarded as being the same. Thus, even when each PV device characteristic is unknown, a plurality of customer facilities 500 each have the PV power generation amount proportional to the insolation. The actual loads of a plurality of customer facilities 500 are each a sum of the operations of a device that consumes power in each customer facility 500, and thus can be regarded as a random variable. Thus, the actual load and the PV power generation amount can be regarded as having no correlation, whereby the method for estimating the actual load and the PV power generation amount described above can be applied.

In this embodiment, the PV power generation amount and the actual load in each customer facility 500 can be separated from each other by using the insolation in an area and apparent loads of a plurality of customer facilities 500 in the area.

The management server 410 may calculate the purchase price of the power generated by the PV device 510 of each customer facility 500 from the PV power generation amount calculated by a power monitoring apparatus. The management server 410 may calculate the price of power consumed by each customer facility 500 from the actual load calculated by the power monitoring apparatus.

At least part of the configurations of this invention can be implemented by a computer program or a hardware circuit. The computer program may be distributed through a storage medium such as a hard disk or a flash memory device.

The technique described in the embodiments above can be described as follows.

(Description 1)

A power monitoring apparatus including:

an acquisition unit configured to acquire, for a first electrical facility including a first solar power generation device and a first load device, a first insolation signal indicating change of insolation to the first solar power generation device over time and a first load signal indicating change of a load, as a combination of the first solar power generation device and the first load device, over time, from a storage device;

a calculation unit configured to calculate a first power generation characteristic indicating a characteristic of a power generation amount of the first solar power generation device with respect to the first insolation signal, based on the first insolation signal and the first load signal.

The technique described in the embodiments above can be described as follows.

(Description 2)

A power monitoring method including:

acquiring, for a first electrical facility including a first solar power generation device and a first load device, a first insolation signal indicating change of insolation to the first solar power generation device over time and a first load signal indicating change of a load, as a combination of the first solar power generation device and the first load device, over time, from a storage device; and

calculating a first power generation characteristic indicating a characteristic of a power generation amount of the first solar power generation device with respect to the first insolation signal, based on the first insolation signal and the first load signal.

The technique described in the embodiments above can be described as follows.

(Description 3)

A computer readable medium storing a program causing a computer to execute:

acquiring, for a first electrical facility including a first solar power generation device and a first load device, a first insolation signal indicating change of insolation to the first solar power generation device over time and a first load signal indicating change of a load, as a combination of the first solar power generation device and the first load device, over time, from a storage device; and

calculating a first power generation characteristic indicating a characteristic of a power generation amount of the first solar power generation device with respect to the first insolation signal, based on the first insolation signal and the first load signal.

The terms in these descriptions are described. The first electrical facility corresponds to, for example, the customer facility 500, the customer facility 500 of the first customer, and the adjacent customer facility 500. The acquisition unit corresponds to for example, to the selection unit 213. The storage device corresponds to, for example, the storage unit 222. The first insolation signal corresponds to, for example, the insolation I(t), I1(t). The first load signal corresponds to, for example, the apparent load Ps(t), Ps1(t). The first power generation characteristic corresponds to, for example, the PV device characteristic K, K1. The first power generation amount signal corresponds to, for example, the PV power generation amount V(t), V1(t). The first actual load signal corresponds to, for example, the actual load P(t), P1(t).

The second electrical facility corresponds to, for example, the customer facility 500 of the second customer. The second insolation signal corresponds to, for example, the insolation I2(t). The second load signal corresponds to, for example, the apparent load Ps2(t). The second power generation characteristic corresponds to, for example, the PV device characteristic K2. The second power generation amount signal corresponds to, for example, the PV power generation amount V2(t). The second actual load signal corresponds to, for example, the actual load P2(t). The third electrical facility corresponds to, for example, the remaining customer facility 500.

### REFERENCE SIGNS LIST

101 Power monitoring apparatus

102 Power monitoring unit

103 Management unit

201, 202 Buffer memory

203 PV device characteristic calculation unit

204 PV power generation amount calculation unit

205 Actual load calculation unit

211 Reception unit

212 Transmission unit

213 Selection unit

221 Calculation unit

222 Storage unit

300 Connection point

400 Electrical grid

410, 410b Management server

420 Communication network

500 Customer facility

510 PV device

511 PV panel

520 Actual load device

530a, 530b, 530c, 530d, 530e Power meter

1. A power monitoring apparatus comprising:
an acquisition unit configured to acquire, for a first electrical facility including a first solar power generation device and a first load device, a first insolation signal indicating change of insolation to the first solar power generation device over time and a first load signal indicating change of a load, as a combination of the first solar power generation device and the first load device, over time, from a storage device;
a calculation unit configured to calculate a first power generation characteristic indicating a characteristic of a power generation amount of the first solar power generation device with respect to the first insolation signal, based on the first insolation signal and the first load signal.

2. The power monitoring apparatus according to claim 1, wherein the calculation unit is configured to calculate the first power generation characteristic based on a correlation between the first insolation signal and a first actual load signal indicating change of a load of the first load device over time.

3. The power monitoring apparatus according to claim 2, wherein the calculation unit is configured to calculate a first power generation amount signal indicating change of a power generation amount of the first solar power generation device over time, based on the first insolation signal and the first power generation characteristic.

4. The power monitoring apparatus according to claim 3, wherein the calculation unit is configured to calculate the first power generation characteristic under a condition according to which a correlation coefficient indicating the correlation is equal to or smaller than a predetermined threshold.

5. The power monitoring apparatus according to claim 3, wherein
the first power generation amount signal is proportional to the first insolation signal, and
the first power generation characteristic is a proportionality constant for the proportionality.

6. The power monitoring apparatus according to claim 3, wherein the calculation unit is configured to calculate the first actual load signal based on the first load signal and the first power generation amount signal.

7. The power monitoring apparatus according to claim 2, wherein
a plurality of the insolation signals indicating the change of the insolation to the first solar power generation device over time are respectively measured in a plurality of time periods and are stored in the storage device,
a plurality of the load signals indicating the change of the load as the combination of the first solar power generation device and the first load device are respectively measured in the plurality of time periods and are stored in the storage device, and
the acquisition unit is configured to select a time period as a selected time period from the plurality of time periods based on magnitudes of fluctuation of the plurality of insolation signals, select as the first insolation signal, a signal measured in the selected time period from the plurality of insolation signals, and select as the first load signal, a signal measured in the selected time period from the plurality of load signals.

8. The power monitoring apparatus according to claim 7, wherein the acquisition unit is configured to select an insolation signal with a largest fluctuation magnitude from the plurality of insolation signals, and select as the selected time period, a time period corresponding to the selected insolation signal from the plurality of time periods.

9. The power monitoring apparatus according to claim 3, wherein
the first electrical facility is provided in a predetermined area,
the acquisition unit is configured to acquire, for a second electrical facility as an electrical facility that is provided in the area and includes a second solar power generation device and a second load device, a second load signal indicating change of a load, as a combination of the second solar power generation device and the second load device, over time, from the storage device, and
the calculation unit is configured to calculate a second power generation characteristic indicating a characteristic of a power generation amount of the second solar power generation device corresponding to the first insolation signal, based on the first insolation signal and the second load signal.

10. The power monitoring apparatus according to claim 3, wherein
the first electrical facility is provided in a predetermined area,
the acquisition unit is configured to acquire, for a third electrical facility as an electrical facility that is provided in the area and includes a third solar power generation device and a third load device, a third load signal indicating change of a load, as a combination of the third solar power generation device and the third load device, over time, from the storage device, and
the calculation unit is configured to calculate a third power generation characteristic indicating a characteristic of a power generation amount of the third solar power generation device corresponding to the first power generation amount signal, based on the first power generation amount signal and the third load signal.

11. A power monitoring method comprising:
acquiring, for a first electrical facility including a first solar power generation device and a first load device, a first insolation signal indicating change of insolation to the first solar power generation device overtime and a first load signal indicating change of a load, as a combination of the first solar power generation device and the first load device, over time, from a storage device; and
calculating a first power generation characteristic indicating a characteristic of a power generation amount of the first solar power generation device with respect to the first insolation signal, based on the first insolation signal and the first load signal.
